(19) United States
(12) Patent Application Publication
(10) Pub. No.: US 2012/0108077 A1
(43) Pub. Date: May 3, 2012

(54) SUBSTRATE PROCESSING APPARATUS AND SEMICONDUCTOR DEVICE MANUFACTURING METHOD

(75) Inventors: Yukinao KAGA, Toyama (JP); Tatsuyuki SAITO, Toyama (JP); Masanori SAKAI, Toyama (JP); Takashi YOKOGAWA, Toyama (JP)

(73) Assignee: HITACHI KOKUSAI ELECTRIC INC., Tokyo (JP)

(21) Appl. No.: 13/231,984

(22) Filed: Sep. 14, 2011

(30) Foreign Application Priority Data
Oct. 29, 2010 (JP) 2010-243809
Aug. 23, 2011 (JP) 2011-181944

(51) Int. Cl. H01L 21/316; H01L 21/314; C23C 16/34; C23C 16/458; C23C 16/52; H01L 21/318; C23C 16/455

(52) U.S. Cl. 438/771; 438/776; 438/769; 118/696; 257/E21.283; 257/E21.292; 257/E21.266

(57) ABSTRACT

Disclosed is a substrate processing apparatus that includes: a substrate supporting member that supports a substrate; a processing chamber capable of housing the substrate supporting member; a rotating mechanism that rotates the substrate supporting member; a carrying mechanism that carries out the substrate supporting member from the processing chamber; a material gas supply system that supplies material gas into the processing chamber; a nitrogen-containing-gas supply system that supplies nitrogen containing gas into the processing chamber; and a controller that controls the material gas supply system, the nitrogen-containing-gas supply system, the carrying mechanism, and the rotating mechanism, after forming a nitride film on the substrate by using the material gas and the nitrogen containing gas, to carry out the substrate supporting member that supports the substrate while being rotated from the processing chamber.

### CROSS-REFERENCE TO RELATED APPLICATION

This application claims priority under 35 USC 119 from Japanese Patent Application No. 2010-243809 filed on Oct. 29, 2010 and Japanese Patent Application No. 2011-181944 filed on Aug. 23, 2011, the disclosures of which are incorporated by reference herein.

### BACKGROUND

1. Technical Field

The present invention relates to a substrate processing apparatus and a method of manufacturing a semiconductor device, and more particularly, to a substrate processing apparatus for forming a titanium nitride film on a substrate and a method of manufacturing a semiconductor device including a step of forming a titanium nitride film on a substrate using the apparatus.

2. Related Art

A film forming apparatus for forming a nitride film such as a titanium nitride film in a processing chamber by using material gas and nitrogen containing gas is disclosed (See Japanese Patent Application Laid-Open (JP-A) No. 2011-58067.)

However, after forming a nitride film such as a titanium nitride film on a substrate such as a semiconductor wafer by using such an apparatus, when the substrate is carried out from the processing chamber, a problem occurs such that a nonuniform natural oxide film is formed on the nitride film, and the properties of the nitride film become nonuniform within a substrate plane.

A main object of the present invention is to provide a substrate processing apparatus and a method of manufacturing a semiconductor device, realizing improved uniformity in the properties of a nitride film formed by using material gas and nitrogen containing gas.

### SUMMARY

According to a first aspect of the present invention, there is provided a substrate processing apparatus including:

a substrate supporting member that supports a substrate;

a processing chamber capable of housing the substrate supporting member;

a rotating mechanism that rotates the substrate supporting member;

a carrying mechanism that carries out the substrate supporting member from the processing chamber;

a material gas supply system that supplies material gas into the processing chamber;

a nitrogen-containing-gas supply system that supplies nitrogen containing gas into the processing chamber; and

a controller that controls the material gas supply system, the nitrogen-containing-gas supply system, the carrying mechanism, and the rotating mechanism, after forming a nitride film on the substrate by using the material gas and the nitrogen containing gas, to carry out the substrate supporting member that supports the substrate while being rotated from the processing chamber.

According to second aspect of the present invention, there is provided a method of manufacturing a semiconductor device, including:

carrying a plurality of substrates into a processing chamber;

forming a film on each of the plurality of substrates by supplying a plurality of gases to the processing chamber; and

carrying out the plurality of substrates from the processing chamber so that an amount of natural oxidation on a surface of the film formed on each of the plurality of substrates becomes a predetermined value in a plane of the substrate.

According to a third aspect of the present invention, there is provided a method of manufacturing a semiconductor device, including:

carrying a substrate supporting member that supports a substrate into a processing chamber;

supplying a material gas and a nitrogen containing gas to the processing chamber to form a nitride film on the substrate; and

carrying out the substrate supporting member that supports the substrate on which the nitride film is formed from the processing chamber while rotating the substrate supporting member.

According to a fourth aspect of the present invention, there is provided a 6method of manufacturing a semiconductor device, including:

carrying a substrate into a processing chamber; supplying a material gas and a nitrogen containing gas to the processing chamber to form a nitride film on the substrate;

supplying an oxygen containing gas to the processing chamber to oxidize a surface of the nitride film; and

thereafter carrying out the substrate from the processing chamber. and

thereafter removing an oxidized film on the surface of the nitride film.

### BRIEF DESCRIPTION OF THE DRAWINGS

An exemplary embodiment of the present invention will be described in detail based on the following figures, wherein:

FIG. 1 is a schematic perspective diagram for explaining a configuration of a substrate processing apparatus preferably used in preferred embodiments of the present invention;

FIG. 2 is a schematic vertical section, taken along the line B-B of FIG. 3, of a portion of a processing furnace, for explaining an example of the processing furnace and members accompanying the processing furnace preferably used in a first preferred embodiment of the present invention;

FIG. 3 is a schematic transverse section taken along the line A-A of the processing furnace shown in FIG. 2;

FIG. 4 is a block diagram for explaining a controller preferably used in the substrate processing apparatus of the first preferred embodiment of the present invention and members to be controlled by the controller;

FIG. 5 is a flowchart for explaining a process of forming a titanium nitride film by using the substrate processing apparatus of the first preferred embodiment of the present invention;

FIG. 6 is a timing chart for explaining a process of forming a titanium nitride film by using the substrate processing apparatus of the first preferred embodiment of the present invention;

FIG. 7 is a schematic vertical section, taken along the line D-D of FIG. 8, of a portion of a processing furnace, for explaining an example of the processing furnace and members accompanying the processing furnace preferably used in a second preferred embodiment of the present invention;

FIG. 8 is a schematic transverse section taken along the line C-C of the processing furnace shown in FIG. 7;

FIG. 9 is a block diagram for explaining a controller preferably used in the substrate processing apparatus of the second preferred embodiment of the present invention and members controlled by the controller;

FIG. 10 is a flowchart for explaining a process of forming a titanium nitride film by using the substrate processing apparatus of the second preferred embodiment of the present invention; and

FIG. 11 is a timing chart for explaining a process of forming a titanium nitride film by using the substrate processing apparatus of the second preferred embodiment of the present invention.

### DETAILED DESCRIPTION

Preferred embodiments of the present invention will be described below with reference to the drawings.

First, a substrate processing apparatus suitably used in each of the preferred embodiments of the present invention will be described. The substrate processing apparatus is constructed as an example of a semiconductor manufacturing apparatus used to manufacture a semiconductor device.

In the following description, the case of using a vertical type apparatus of performing a film forming process or the like on a substrate as an example of a substrate processing apparatus will be stated. The precondition of the present invention, however, is not use of a vertical type apparatus but, for example, a single-wafer processing apparatus may be used.

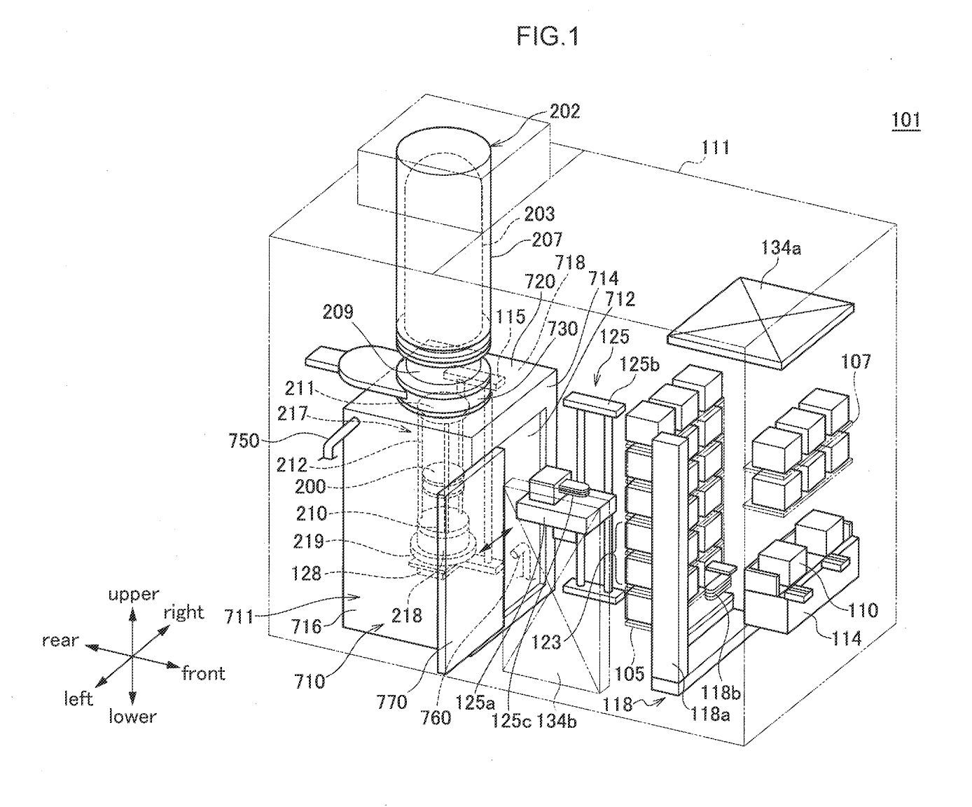

Referring to FIG. 1, in a substrate processing apparatus 101, a cassette 110 housing wafers 200 as an example of a substrate is used, and the wafers 200 are made of a material such as semiconductor silicon. The substrate processing apparatus 101 has a casing 111, and a cassette stage 114 is set in the casing 111. The cassette 110 is carried onto the cassette stage 114 by an in-process carrying apparatus (not illustrated) or carried out from the cassette stage 114.

The cassette 110 is put on the cassette stage 114 so that the wafers 200 in the cassette 110 hold a vertical posture and a wafer carry-in/out port in the cassette 110 faces upward by the in-process carrying apparatus (not shown). The cassette stage 114 can be operated so that the cassette 110 is turned by 90° in the clockwise and vertical direction to the rear side of the casing 111, the wafers 200 in the cassette 110 come to have a horizontal posture, and the wafer carry-in/out port in the cassette 110 faces the rear side of the casing 111.

A cassette rack 105 is set on the front side with respect to the center in the longitudinal direction in the casing 111, and is configured to store a plurality of cassettes 110 in a plurality of rows and a plurality of columns. The cassette rack 105 is provided with a transfer rack 123 in which a cassette 110 to be carried by a wafer transfer mechanism 125 is housed.

A spare cassette rack 107 is provided above the cassette stage 114 and is configured as a spare to store the cassettes 110.

A cassette carrying apparatus 118 is set between the cassette stage 114 and the cassette rack 105. The cassette carrying apparatus 118 has a cassette elevator 118a that can elevate the cassette 110 while holding it and a cassette carrying mechanism 118b as a carrying mechanism. The cassette carrying apparatus 118 carries the cassette 110 among the cassette stage 114, the cassette rack 105, and the spare cassette rack 107 by interlocking operation between the cassette elevator 118a and the cassette carrying mechanism 118b.

The wafer transfer apparatus 125 is mounted at the rear of the cassette rack 105. The wafer transfer apparatus 125 has a wafer transfer mechanism 125a capable of turning the wafer 200 or moving the wafer 200 straight in the horizontal direction and a wafer transfer mechanism elevator 125b for elevating the wafer transfer mechanism 125a. The wafer transfer mechanism 125a is provided with tweezers 125c for picking up the wafers 200. The wafer transfer apparatus 125 uses the tweezers 125c as a pickup of the wafer 200 to charge the wafer 200 to a boat 217 or discharge the wafer 200 from the boat 217 by interlocking operation of the wafer transfer mechanism 125a and the wafer transfer mechanism elevator 125b.

Above the cassette rack 105, a cleaning unit 134a for supplying clean air as cleaned atmosphere is mounted. The cleaning unit 134a has a supply fan (not shown) and a dustproof filter (not shown). The clean air flows in the casing 111 and, after that, is exhausted to the outside of the casing 111.

A cleaning unit 134b for supplying clean air is set at a left-side end of the casing 111. The cleaning unit 134b also has a supply fan (not shown) and a dustproof filter (not shown) and makes clean air flow around the wafer transfer mechanism 125a and the like. The clean air flows around the wafer transfer mechanism 125a and the like and is exhausted to the outside of the casing 111.

A processing furnace 202 for performing heat treatment on the wafer 200 is provided on a rear part of the casing 111. A casing (hereinbelow, called a pressure-tight casing) 711 having airtightness which can maintain the pressure less than the atmospheric pressure (hereinbelow, called negative pressure) is set below the processing furnace 202. A load lock chamber 710 as a load-lock-type standby chamber having volume which can house the boat 217 is formed by the pressure-tight casing 711.

### First Embodiment

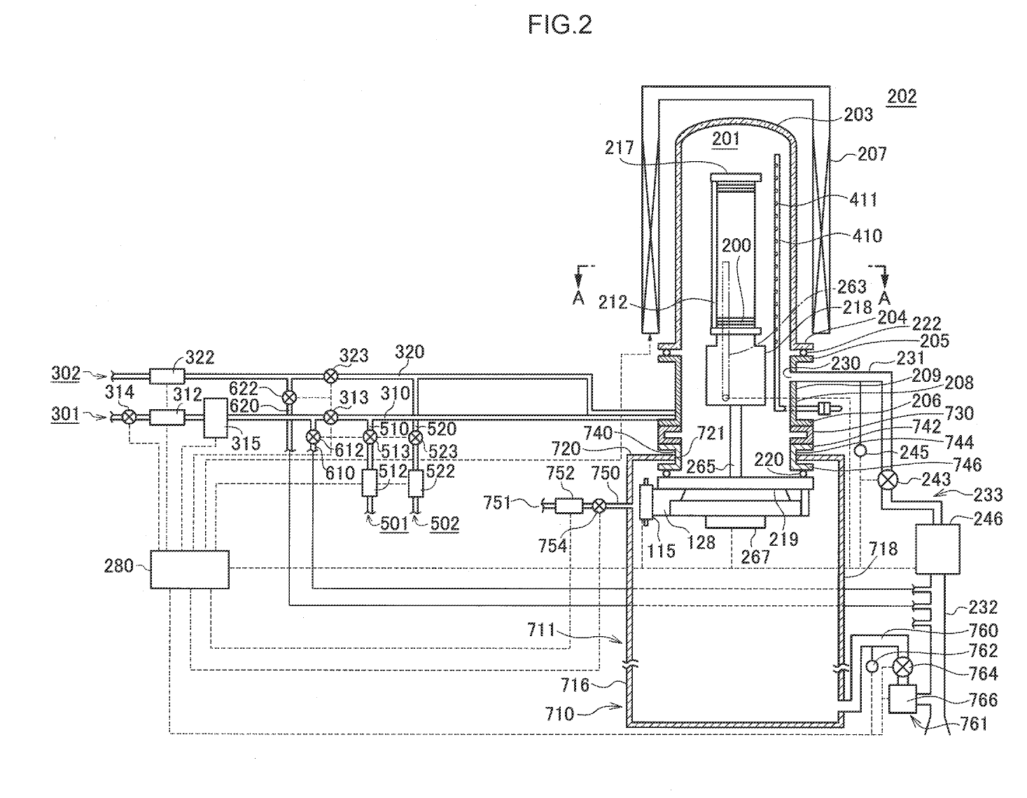

Referring to FIGS. 1 and 2, the processing furnace 202 is provided with a heater 207 as a heating device (heating means) for heating the wafer 200. The heater 207 has a cylindrical-shaped heat insulating member whose upper end is closed and a plurality of heater wires, and has a unit configuration in which the heater wires are provided with respect to the heat insulating member. In the heater 207, a reaction tube 203 made of quartz for processing the wafer 200 is provided concentrically with the heater 207.

A manifold 209 is provided below the reaction tube 203. An annular flange 204 is provided on the outside of a lower opening of the reaction tube 203. The manifold 209 has a cylindrical side wall 208 and annular flanges 205 and 206 provided on the outside of upper and lower openings, respectively, of the side wall 208. An O-ring 222 as an airtight member is disposed between the flange 204 of the reaction tube 203 and the flange 205 on the upper side of the manifold 209, and the flanges are air-tightly sealed.

A gate valve 730 is attached to the lower side of the manifold 209. The gate valve 730 is attached to the flange 206 on the lower side of the manifold 209 so that the lower end of the manifold 209 is opened/closed by the gate valve 730.

The gate valve 730 is attached to the pressure-tight casing 711 via an attachment member 740. A through hole 721 is provided in a ceiling 720 of the pressure-tight casing 711, and the attachment member 740 is attached to the through hole 721. The attachment member 740 has a cylindrical side wall 744 and annular flanges 742 and 746 provided on the outside of upper and lower openings, respectively, of the sidewall 744. The ceiling 720 of the pressure-tight casing 711 is attached to the side wall 744 of the attachment member 740. The gate valve 730 is attached to the upper-side flange 742 of the attachment member 740.

In the load lock chamber 710 formed by the pressure-tight casing 711, a boat elevator 115 for elevating the boat 217 to the reaction tube 203 is provided. An arm 128 is coupled to an elevation stand of the boat elevator 115. The arm 128 is provided with a seal cap 219 as a furnace cover which can air-tightly close the lower-end opening of the attachment member 740.

The seal cap 219 comes into contact with the lower end of the attachment member 740 from below in the vertical direction. The seal cap 219 is made of, for example, a metal such as stainless steel and is formed in a disc shape. A hermetic member (hereinbelow, called O-ring) 220 is disposed between the annular flange 746 provided at the periphery of the lower-end opening of the attachment member 740 and the top face of the seal cap 219. The flange 746 and the top face are hermetically sealed. A processing chamber 201 is formed by at least the reaction tube 203, the manifold 209, the attachment member 740, and the seal cap 219.

A boat supporting stand 218 supporting the boat 217 is provided over the seal cap 219 via a rotary shaft 265 which will be described later. The boat supporting stand 218 is made of, for example, a heat-resisting material such as quartz or silicon carbide, functions as a heat resisting unit, and also serves as a supporting member which supports the boat 217. The boat 217 is provided upright on the boat supporting stand 218. The boat 217 is made of, for example, a heat-resisting material such as quartz or silicon carbide. The boat 217 has a bottom plate 210 fixed to the boat supporting stand 218 and a top plate 211 disposed above the bottom plate 210. A plurality of support pillars 212 are provided between the bottom plate 210 and the top plate 211. The boat 217 holds a plurality of wafers 200. The plurality of wafers 200 are stacked in multiple stages at regular intervals in the axial direction of the reaction tube 203 in a state where their horizontal postures are maintained and their centers are aligned.

A boat rotating mechanism 267 for rotating the boat 217 is provided on the side opposite to the processing chamber 201 of the seal cap 219. The rotary shaft 265 of the boat rotating mechanism 267 penetrates the seal cap 219, is connected to the boat supporting stand 218, and rotates the boat 217 via the boat supporting stand 218 by the rotating mechanism 267 to rotate the wafer 200.

The seal cap 219 is moved in the vertical directions by the boat elevator 115 as an elevating mechanism provided on the outside of the reaction tube 203, thereby enabling the boat 217 to be carried into/from the processing chamber 201.

The reaction tube 203, the wafers 200, the boat 217, the boat supporting stand 218, and the rotary shaft 265 are provided concentrically.

A wafer carry-in/out port 712 is opened in a front wall 714 of the pressure-tight casing 711 and is closed by a gate valve 770. A gas supply pipe 750 for supplying inert gas such as nitrogen gas to the load rock chamber 710 is connected to a left sidewall 716 of the pressure-tight casing 711, and an exhaust pipe 760 for evacuating the air in the load lock chamber 141 is connected to a right sidewall 718.

The gas supply pipe 750 is provided with, in order from the upstream side, a mass flow controller 752 as a flow controller and a valve 754 as an open/close valve. A gas supply system 751 to the load lock chamber 710 is constructed mainly by the gas supply pipe 750, the mass flow controller 752, and the valve 754.

To the exhaust pipe 760, a pressure sensor 762 as a pressure detector (pressure detecting unit) for detecting pressure in the load lock chamber 710 is connected and a vacuum pump 766 as an evacuation device is connected via a valve 764 as an open/close valve. With the configuration, the load lock chamber 710 is evacuated so that the pressure in the load lock chamber 710 becomes predetermined pressure (vacuum). The downstream side of the vacuum pump 764 is connected to an exhaust pipe 232. An exhaust system 761 of the load lock chamber 710 is constructed mainly by the exhaust pipe 760, the pressure sensor 762, the valve 764, and the vacuum pump 766.

In the above-described processing furnace 202 and the load lock chamber 710, the gate valve 770 is opened and a plurality of wafers 200 to be batch-processed are transferred so as to be stacked in multiple stages on the boat 217 by the wafer transfer apparatus 125 from the cassette 110 housed in the transfer rack 123 of the cassette rack 105 via the wafer carry-in/out port 712. In a state where the gate valve 770 is closed and the gate valve 730 is also closed, the load lock chamber 710 is exhausted by the exhaust system 761. After that, the pressure in the load lock chamber 710 is set to atmospheric pressure with nitrogen gas by the gas supply pipe 751. Then, the gate valve 730 is opened and the boat 217 is inserted in the processing chamber 201 heated by the heater 207 to predetermined temperature. The opening at the lower end of the attachment member 740 is hermetically closed with the seal cap 219, and the wafers 200 are processed in the processing chamber 201. After completion of the processing on the wafers 200, the boat 217 is lowered and carried out from the processing chamber 201. The gate valve 730 is closed, the gate valve 770 is opened, and the wafers 200 are carried out from the load lock chamber 710 by the wafer transfer apparatus 125 via the wafer carry-in/out port 712 and transferred to the cassette 110 housed in the transfer rack 123 of the cassette rack 105.

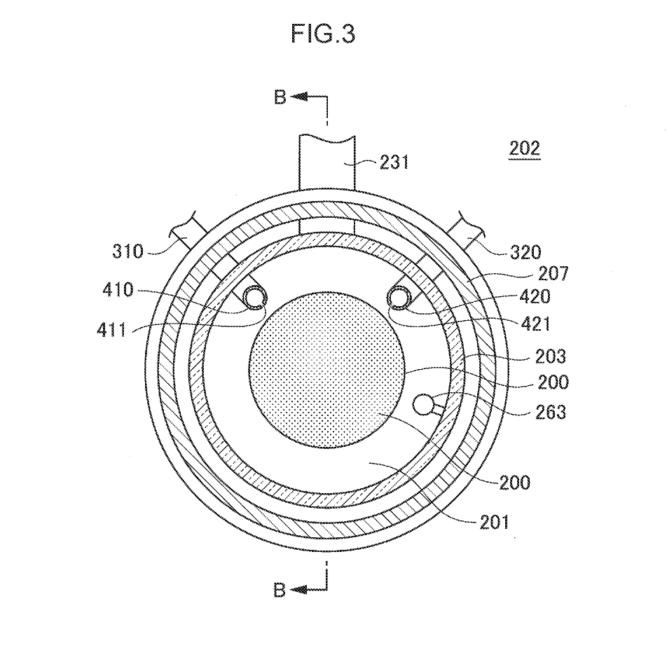

Referring to FIGS. 2 and 3, two gas supply pipes 310 and 320 for supplying material gas are provided.

The gas supply pipe 310 is provided with, in order from the upstream side, a valve 314 as an open/close valve, a liquid mass flow controller 312 as a flow controller (flow controlling unit), a vaporizer 315 as a vaporizing unit (vaporizing means), and a valve 313 as an open/close valve.

The downstream-side end of the gas supply pipe 310 penetrates the manifold 209, and the lower end of a nozzle 410 is connected to the front end of the gas supply pipe 310 in the manifold 209. The nozzle 410 extends in the vertical direction along the inner wall of the reaction tube 203 (the stack direction of the wafers 200) in a circular space between the inner wall of the reaction tube 203 and the wafers 200. A number of gas supply holes 411 for supplying material gas are provided in the side face of the nozzle 410. The gas supply holes 411 have the same opening area or opening areas which change from the bottom to the top and are provided at the same pitch. The gas supply holes 411 are open toward the center of the reaction tube 203.

Further, the gas supply pipe 310 is provided with, between the vaporizer 315 and the valve 313, a vent line 610 connected to the exhaust pipe 232 which will be described later and a valve 612.

A gas supply system (gas supplying unit) 301 is constructed mainly by the gas supply pipe 310, the valve 314, the liquid mass flow controller 312, the vaporizer 315, the valve 313, the nozzle 410, the vent line 610, and the valve 612.

To the gas supply pipe 310, a carrier gas supply pipe 510 for supplying carrier gas is connected on the downstream side of the valve 313. The carrier gas supply pipe 510 is provided with a mass flow controller 512 and a valve 513. A carrier gas supply system (inert gas supply system, inactive gas supplying unit) 501 is constructed mainly by the carrier gas supply pipe 510, the mass flow controller 512, and the valve 513.

In the gas supply pipe 310, liquid material is subjected to flow adjustment by the liquid mass flow controller 312, the resultant material is supplied to the vaporizer 315 and is vaporized, and the resultant is supplied as material gas.

While no material gas is supplied to the processing chamber 201, the valve 313 is closed, the valve 612 is opened, and the material gas is passed to the vent line 610 via the valve 612.

At the time of supplying the material gas to the processing chamber 201, the valve 612 is closed, the valve 313 is opened, and the material gas is supplied to the gas supply pipe 310 on the downstream side of the valve 313. On the other hand, carrier gas is subjected to flow adjustment in the mass flow controller 512, and the resultant gas is supplied from the carrier gas supply pipe 510 via the valve 513. The material gas joins to the carrier gas on the downstream side of the valve 313, and the gases are supplied to the processing chamber 201 via the nozzle 410.

The gas supply pipe 320 is provided with, in order from the upstream side, a mass flow controller 322 as a flow controller (flow controlling unit) and a valve 323 as an open/close valve.

The downstream-side end of the gas supply pipe 320 penetrates the manifold 209, and the lower end of a nozzle 420 is connected to the front end of the gas supply pipe 320 in the manifold 209. The nozzle 420 extends in the vertical direction along the inner wall of the reaction tube 203 (the stack direction of the wafers 200) in a circular space between the inner wall of the reaction tube 203 and the wafers 200. A number of gas supply holes 421 for supplying material gas are provided in the side face of the nozzle 420. The gas supply holes 421 have the same opening area or opening areas which change from the bottom to the top and are provided at the same pitch. The gas supply holes 421 are open toward the center of the reaction tube 203.

Further, the gas supply pipe 320 is provided with, between the mass flow controller 322 and the valve 323, a vent line 620 connected to the exhaust pipe 232 which will be described later and a valve 622.

A gas supply system (gas supplying unit) 302 is constructed mainly by the gas supply pipe 320, the mass flow controller 322, the valve 323, the nozzle 420, the vent line 620, and the valve 622. In the first and second embodiments, the gas supply system 302 is used as a nitrogen containing gas supply system for supplying nitrogen containing gas to the processing chamber 201.

To the gas supply pipe 320, a carrier gas supply pipe 520 for supplying carrier gas is connected on the downstream side of the valve 323. The carrier gas supply pipe 520 is provided with a mass flow controller 522 and a valve 523. A carrier gas supply system (inert gas supply system, inactive gas supplying unit) 502 is constructed mainly by the carrier gas supply pipe 520, the mass flow controller 522, and the valve 523.

In the gas supply pipe 320, gaseous material gas is subjected to flow adjustment by the mass flow controller 322, and the resultant is supplied.

While no material gas is supplied to the processing chamber 201, the valve 323 is closed, the valve 622 is opened, and the material gas is passed to the vent line 620 via the valve 622.

At the time of supplying the material gas to the processing chamber 201, the valve 622 is closed, the valve 323 is opened, and the material gas is supplied to the gas supply pipe 320 on the downstream side of the valve 323. On the other hand, carrier gas is subjected to flow adjustment in the mass flow controller 522, and the resultant gas is supplied from the carrier gas supply pipe 520 via the valve 523. The material gas joins to the carrier gas on the downstream side of the valve 323, and the gases are supplied to the processing chamber 201 via the nozzle 420.

The manifold has an exhaust port 230. To the exhaust port 230, an exhaust pipe 231 for exhausting atmosphere in the processing chamber 201 is connected. To the exhaust pipe 231, a pressure sensor 245 as a pressure detector (pressure detecting unit) for detecting the pressure in the processing chamber 201 is connected, and a vacuum pump 246 as a vacuum exhausting device is connected via an APC (Auto Pressure Controller) valve 243 as a pressure adjustor (pressure adjusting unit). With the configuration, the processing chamber 201 can be evacuated so that the pressure in the processing chamber 201 becomes predetermined pressure (vacuum). The exhaust pipe 232 on the downstream side of the vacuum pump 246 is connected to a waste gas processing apparatus (not shown) or the like. The APC valve 243 is opened/closed to perform/stop evacuation of the processing chamber 201. By adjusting the degree of opening of the APC valve 243, conductance is adjusted, and the pressure in the processing chamber 201 can be adjusted. An exhaust system 233 is constructed mainly by the exhaust pipe 231, the APC valve 243, the vacuum pump 246, and the pressure sensor 245.

A temperature sensor 263 as a temperature detector is mounted in the reaction tube 203. By adjusting power supplied to the heater 207 on the basis of temperature information detected by the temperature sensor 263, the temperature in the processing chamber 201 has a desired temperature distribution. The temperature sensor 263 is formed in an L shape, penetrates the manifold 209, and is provided along the inner wall of the reaction tube 203.

At the time of processing the wafers 200, the boat 217 on which the wafers are mounted is introduced into the reaction tube 203. The boat 217 can be moved vertically in the reaction tube 203 (carried in or carried out from the reaction tube 203) by the boat elevator 115. When the boat 217 is introduced in the reaction tube 203, the flange 746 at the lower end of the attachment member 740 is hermetically sealed by the seal cap 219 via the O-ring 220. The boat 217 is supported by the boat supporting stand 218. To improve uniformity of the processing, the boat rotating mechanism 267 is driven to rotate the boat 217 supported by the boat supporting stand 218.

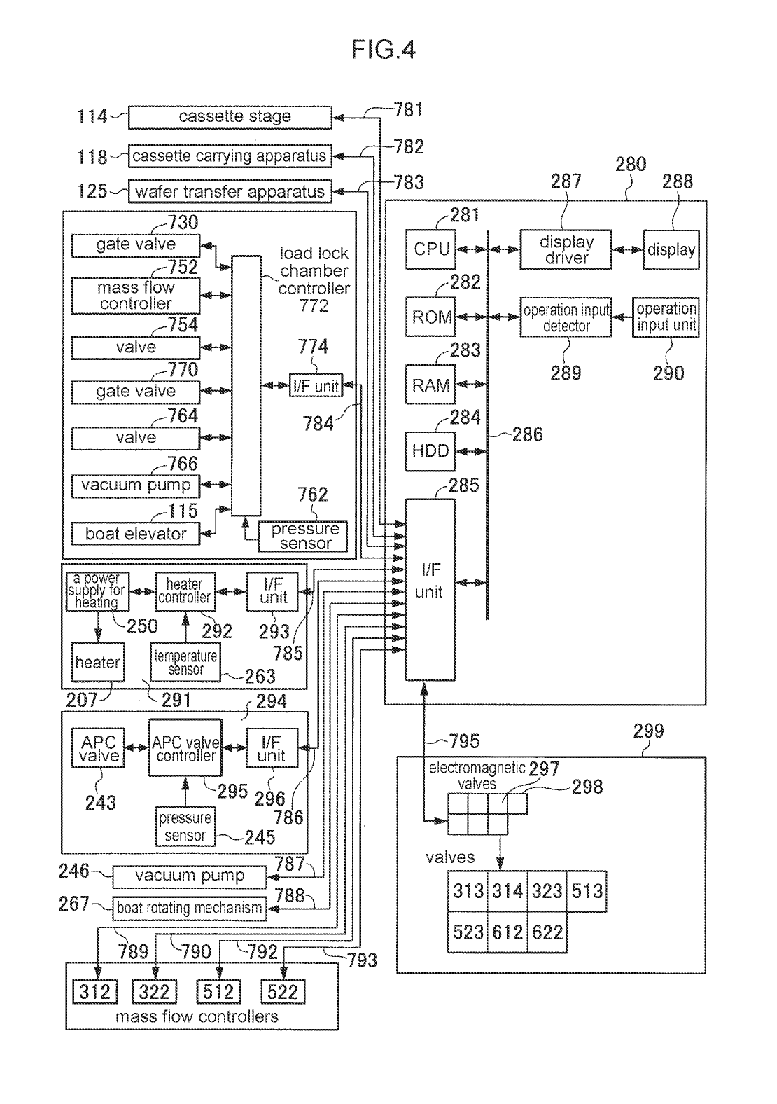

With reference to FIG. 4, a controller 280 has a display 288 for displaying an operation menu and the like and an operation input unit 290 which includes a plurality of keys and to which various information and operation instructions are input. The controller 280 also has: a CPU 281 controlling the entire operation of the substrate processing apparatus 101; a ROM 282 in which various programs including a control program are pre-stored; a RAM 283 for temporarily storing various data; an HDD 284 for storing and retaining various data; a display driver 287 for controlling display of various information to the display 288 and receiving operation information from the display 288; an operation input detector 289 for detecting an operation state of the operation input unit 290; and a communication interface (I/F) unit 285 for transmitting/receiving various information to/from members such as the cassette stage 114, the cassette carrying mechanism 118, the wafer transfer apparatus 125, a load lock chamber controller 772, a temperature controller 291 which will be described later, a pressure controller 294 which will be described later, the vacuum pump 246, the boat rotating mechanism 267, the mass flow controllers 312, 322, 512, and 522, and a valve controller 299 which will be described later.

The CPU 281, ROM 282, RAM 283, HDD 284, display driver 287, operation input detector 289, and communication I/F unit 285 are connected to one another via a system bus 286. Therefore, the CPU 281 can access the ROM 282, RAM 283, and HDD 284, control displaying of various information on the display 288 via the display driver 287, grasp operation information from the display 288, and control transmission/reception of various information to/from the members via the communication I/F unit 285. The CPU 281 can also grasp the operation state of the user on the operation input unit 290 via the operation input detector 289.

To the load lock chamber controller 772, a communication I/F unit 774 is connected, which transmits/receives various information such as open/close information of the gate valve 730 and a gate valve 770, elevation information of the boat elevator 115, and pressure set information of the load lock chamber 710 to/from the controller 280. The communication I/F unit 774 and the communication I/F unit 285 of the controller 280 are connected to each other via a cable 784. The load lock chamber controller 772 performs control on the open/close operation of the gate valves 730 and 770 on the basis of the received open/close information of the gate valves 730 and 770, control on the elevating operation of the boat elevator 115 on the basis of the received elevation information of the boat elevator 115, start/stop control of the vacuum pump 766 on the basis of the received pressure set information and the like of the load lock chamber and pressure information and the like from the pressure sensor 762, flow control of the mass flow controller 752, opening/closing operation of the valves 754 and 764, and the like. The load lock chamber controller 772 is also realized by a computer.

The temperature controller 291 has the heater 207, a power supply 250 for heating which supplies power to the heater 207, a temperature sensor 263, a communication I/F unit 293 for transmitting/receiving various information such as set temperature information to/from the controller 280, and a heater controller 292 for controlling power supply from the power supply 250 for heating to the heater 207 on the basis of the received set temperature information, the temperature information from the temperature sensor 263, and the like. The heater controller 292 is also realized by a computer. The communication I/F unit 293 of the temperature controller 291 and the communication I/F unit 285 of the controller 280 are connected to each other via a cable 785.

The pressure controller 294 has the APC valve 243, the pressure sensor 245, a communication I/F unit 296 for transmitting/receiving various information such as the set pressure information, the open/close information of the APC valve 243, and the like to/from the controller 280, and an APC valve controller 295 for controlling the opening/closing and the degree of opening of the APC valve 243 on the basis of the received set pressure information, the open/close information and the like of the APC valve 243, and the pressure information and the like from the pressure sensor 245. The APC valve controller 295 is also realized by a computer. The I/F unit 296 of the pressure controller 294 and the communication I/F unit 295 of the controller 280 are connected to each other via a cable 786.

The cassette stage 114, the cassette carrying apparatus 118, the wafer transfer apparatus 125, the vacuum pump 246, the boat rotating mechanism 267, the liquid mass flow controller 312, and the mass flow controllers 322, 512, and 522 are connected to the communication I/F unit 285 of the controller 280 via cables 781, 782, 783, 787, 788, 789, 790, 792, and 793, respectively.

The valve controller 299 has the valves 313, 314, 323, 513, 523, 612, and 622 and an electromagnetic valve group 298 for controlling supply of air to the valves 313, 314, 323, 513, 523, 612, and 622 as air valves. The electromagnetic valve group 298 has electromagnetic valves 297 for the valves 313, 314, 323, 513, 523, 612, and 622. The electromagnetic valve group 298 and the communication I/F unit 285 of the controller 280 are connected to each other via a cable 795.

As described above, the members such as the cassette stage 114, the cassette carrying apparatus 118, the wafer transfer apparatus 125, the gate valves 730 and 770, the mass flow controller 752, the valves 754 and 764, the vacuum pump 766, the boat elevator 115, the pressure sensor 762, the power supply 250 for heating, the temperature sensor 263, the APC valve 243, the pressure sensor 245, the vacuum pump 246, the boat rotating mechanism 267, the liquid mass flow controller 312, the mass flow controllers 322, 512, and 522, and the valves 313, 314, 323, 513, 523, 612, and 622 are connected to the controller 280.

The controller 280 performs control on the posture of the cassette 110 by the cassette stage 114, control on operation of carrying the cassette 110 by the cassette carrying apparatus 118, control on operation of transferring the wafer 200 by the wafer transfer apparatus 125, control on operation of opening/closing the gate valves 730 and 770, control on start/stop of the vacuum pump 766, control on the flow of the mass flow controller 752, control on pressure in the load lock chamber 710 through the control on the operation of opening/closing the valves 754 and 764 on the basis of the pressure information from the pressure sensor 762, control on operation of elevating the boat 217 through control on elevating operation of the boat elevator 115, temperature control through operation of adjusting the supply amount of power from the power supply 250 for heating to the heater 207 on the basis of the temperature information from the temperature sensor 263, pressure control through opening-degree adjusting operation based on the control of opening/closing the APC valve 243 and the pressure information from the pressure sensor 245, control on start/stop of the vacuum pump 246, control on adjustment of rotating speed of the boat 217 through the control on adjustment of the rotating speed of the boat rotating mechanism 267, control on flow of the liquid mass flow controller 312 and the mass flow controllers 322, 512, and 522, control on opening/closing operation of the valves 313, 314, 323, 513, 523, 612, and 622, and the like.

Next, an example of semiconductor device manufacturing process for manufacturing an LSI (Large Scale Integration) using the substrate processing apparatus 101 will be described. In the following description, operations of the units constructing the substrate processing apparatus 101 are controlled by the controller 280.

An LSI is subjected to a wafer process of processing a silicon wafer and is manufactured by an assembling process, a test process, and a reliability test process. The wafer process is divided into a substrate process of performing processes such as oxidation and diffusion on a silicon wafer and a wiring process of forming wires on the surface of the silicon wafer. In the wiring process, lithography process is mainly performed and cleaning, heat treatment, film formation, and the like are repetitively executed. In the lithography process, a resist pattern is formed, and etching is performed using the pattern as a mask, thereby processing a layer under the pattern.

Next, a process of forming a titanium nitride (TiN) film used for an electrode, a diffusion barrier, or the like on a silicon wafer by using the substrate processing apparatus 101 will be described.

For example, in the case of CVD (Chemical Vapor Deposition), a plurality of kinds of gases including a plurality of elements constructing a film to be formed are supplied simultaneously. In the case of ALD (Atomic Layer Deposition), a plurality of kinds of gases including a plurality of elements constructing a film to be formed are alternately supplied. By controlling processing parameters at the time of supply, such as the supply flow rate, supply time, and plasma power, for example, a silicon oxide film (SiO film) or a silicon nitride film (SiN film) is formed. In those techniques, for example, in the case of forming an SiO film, the supply parameters are controlled so that the composition ratio of the film becomes “O/Si=approximately 2” as a stoichiometric composition. For example, in the case of forming an SiN film, the supply parameters are controlled so that the composition ratio of the film becomes “N/Si=approximately 1.33” as the stoichiometric composition.

On the other hand, unlike ALD method, the supply parameters can be also controlled so that the composition ratio of a film to be formed becomes a predetermined composition ratio which is different from the stoichiometric composition. Specifically, the supply parameters are controlled so that at least one of a plurality of elements constructing a film to be formed becomes excessive more than the other elements in the stoichiometric composition. As described above, it is also possible to form a film while controlling the proportions of a plurality of elements constructing a film to be formed, that is, relative proportions in the film. In the following, an example of a sequence of forming a titanium nitride film having a stoichiometric composition by alternately supplying a plurality of kinds of gases containing different kinds of elements by the ALD will be described.

An example of forming a titanium nitride film on the semiconductor silicon wafer 200 will be described, in which titanium (Ti) is used as a first element, nitrogen (N) is used as a second element, titanium tetrachloride (TiCl₄) gas obtained by vaporizing titanium tetrachloride (TiCl₄) as a liquid titanium-containing material is used as a material containing the first element, and ammonia (NH₃) gas as nitrogen containing gas is used as a reaction gas containing the second element.

Referring to FIG. 1, when the cassette 110 is carried on the cassette stage 114 by the in-process carrying apparatus (not shown), the cassette 110 is mounted on the cassette stage 114 so that the wafers 200 hold the vertical posture above the cassette stage 114, and the wafer carry-in/out port of the cassette 110 faces upward. After that, the cassette 110 is turned by 90° clockwisely in the vertical direction to the rearward of the casing 111 so that the wafer 200 in the cassette 110 has the horizontal posture and the wafer carry-in/out port of the cassette 110 faces rearward of the casing 111.

Subsequently, the cassette 110 is automatically carried and delivered by the cassette carrying mechanism 118 to a designated rack position in the cassette rack 105 or the spare cassette rack 107 and temporarily stored. After that, the cassette 110 is transferred to the transfer rack 123 from the cassette rack 105 or the spare cassette rack 107 or is directly carried to the transfer rack 123 by the cassette carrying mechanism 118.

When the cassette 110 is transferred to the transfer rack 123, the wafer carry-in/out port 712 in the load lock chamber 710 whose inside is preset to the atmosphere pressure state is opened by the opening operation of the gate valve 770.

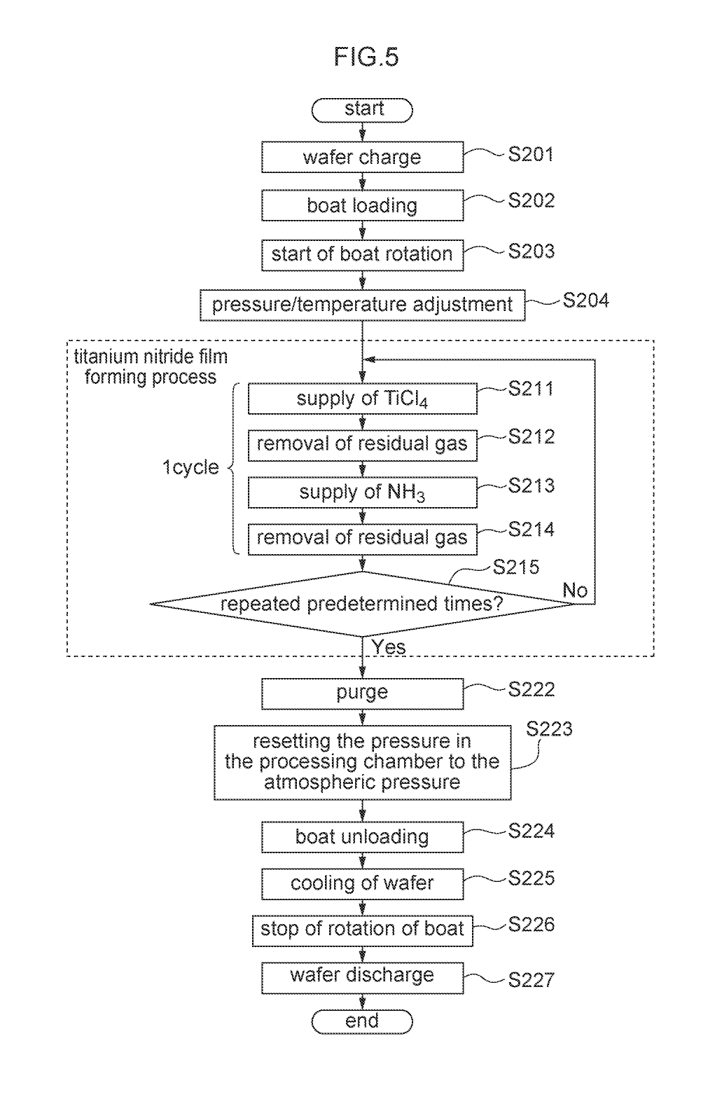

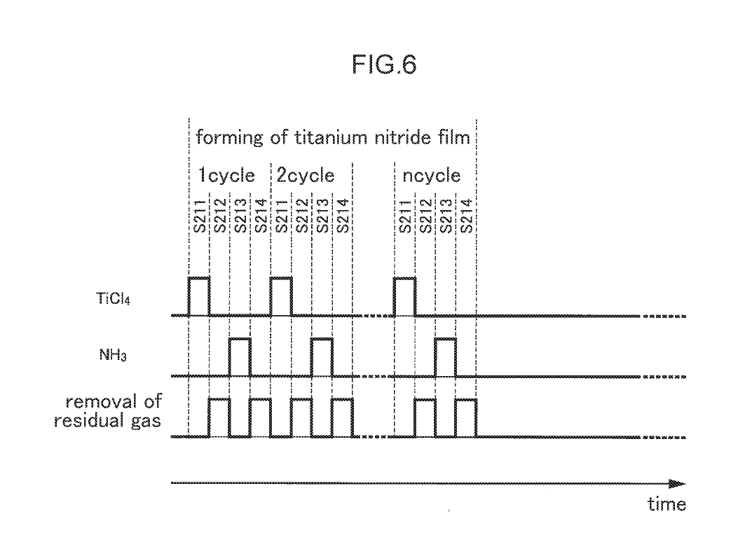

The subsequent processes will be described with reference to the flowchart of FIG. 5 and the timing chart of FIG. 6 in addition to FIGS. 1 and 2.

When the wafer carry-in/out port 712 is opened, the wafers 200 are picked up from the cassette 110 housed in the transfer rack 123 of the cassette rack 105 by the tweezers 125c of the wafer transfer mechanism 125a through the wafer input/output port of the cassette 110, carried into the load lock chamber 710 through the wafer carry-in/out port 712, transferred to the boat 217, and charged (step S201). The wafer transfer mechanism 125a which transferred the wafers 200 to the boat 217 returns to the cassette 110, and charges the next wafers 110 to the boat 217.

The power supply 250 for heating which supplies power to the heater 207 is preliminarily controlled to maintain the inside of the processing chamber 201 to a temperature in the range of 300 to 450° C., for example, 300° C. The processing chamber 201 is closed by the gate valve 730. The inside of the processing chamber 201 is maintained at atmospheric pressure by nitrogen gas as inert gas.

After pre-designated number of wafers 200 to be subjected to batch process are charged so as to be stacked in multiple stages in the boat 217, the wafer carry-in/out port 712 is closed by the gate valve 770. The vacuum pump 766 is started and the valve 764 is opened to exhaust the load lock chamber 710 to reduce the pressure.

After that, the valve 764 is closed, and the valve 754 is opened to supply the nitrogen gas whose flow is adjusted by the mass flow controller 752 to the load lock chamber 710. The pressure in the load lock chamber 710 is measured by the pressure sensor 762. On the basis of the measured pressure, the pressure in the load lock chamber 710 is set to the atmospheric pressure by the nitrogen gas.

When the pressure in the load lock chamber 710 becomes the atmospheric pressure, the gate valve 730 is opened.

After that, the boat 217 supporting the plurality of wafers 200 is elevated by the boat elevator 115 and loaded in the processing chamber 201 heated to predetermined temperature by the heater 207 (step S202). The seal cap 219 hermetically seals the opening at the lower end of the attachment member 740 via the O-ring 220 to obtain a state where the processing chamber 201 is hermetically sealed.

The boat 217 is rotated by the boat rotating mechanism 267 (start boat rotation in step S203) to rotate the wafers 200.

The APC valve 243 is opened to perform vacuuming using the vacuum pump 246 so that the pressure in the processing chamber 201 becomes desired pressure (vacuum), and the temperature of the wafer 200 reaches 380° C. and becomes stable (step S204). In the state where the temperature in the processing chamber 201 is held at 380° C., the following steps are sequentially executed.

The pressure in the processing chamber 201 is measured by the pressure sensor 245. On the basis of the measured pressure, the degree of opening of the APC valve 243 is feedback-controlled (pressure adjustment). The heater 207 is heated so that the temperature in the processing chamber 201 becomes desired temperature. On the basis of information of the temperature detected by the temperature sensor 263, the state of power supply from the power supply 250 for heating to the heater 207 is feedback-controlled (temperature adjustment).

Next, a titanium nitride film forming process of forming a titanium nitride (TiN) film by supplying the titanium tetrachloride (TiCl₄) gas and the ammonia (NH₃) gas into the processing chamber 201 is performed. In the titanium nitride film forming process, four steps (S211 to S214) to be described below are repeatedly executed. In the embodiment, a titanium nitride film is formed by the ALD. In the following, with reference to FIGS. 2, 3, 5, and 6, the titanium nitride film forming process will be described.

Supply of TiCl₄ in Step S211

In step S211, TiCl₄ is supplied from the gas supply pipe 310 of the gas supply system 301 and the nozzle 410 into the processing chamber 201. The valve 313 is closed and the valves 314 and 612 are opened. TiCl₄ is liquid at room temperature. The flow of the liquid TiCl₄ is adjusted by the liquid mass flow controller 312, and the resultant liquid is supplied to the vaporizer 312 and vaporized by the vaporizer 312. Before TiCl₄ is supplied to the processing chamber 201, the valve 313 is closed and the valve 612 is opened to pass TiCl₄ to the vent line 610 via the valve 612.

At the time of supplying TiCl₄ to the processing chamber 201, the valve 612 is closed and the valve 613 is opened to supply TiCl₄ to the gas supply pipe 310 on the downstream of the valve 313, and the valve 513 is opened to supply carrier gas (N₂) from the carrier gas supply pipe 510. The flow of the carrier gas (N₂) is controlled by the mass flow controller 512. TiCl₄ is joined together and mixed with the carrier gas (N₂) on the downstream side of the valve 313. The mixture is exhausted from the exhaust pipe 231 while being supplied to the processing chamber 201 via the gas supply hole 411 in the nozzle 410. At this time, the APC valve 243 is properly adjusted to maintain the pressure in the processing chamber 201 to the range from 30 to 100 Pa, for example, at 35 Pa. The supply amount of TiCl₄ controlled by the liquid mass flow controller 312 is set to the range of 1 to 2 g/min, for example, 1.5 g/min. Time of exposing the wafer 200 to TiCl₄ lies in the range of three seconds to 60 seconds and is, for example, five seconds. By controlling the power supply 250 for heating which supplies power to the heater 207, the temperature in the processing chamber 201 is held at, for example, 380° C.

At this time, the gas flowing in the processing chamber 201 is only TiCl₄ and N₂ as inert gas, and NH₃ does not exist. Therefore, TiCl₄ makes a surface reaction (chemical adsorption) with the surface or an underlayer film of the wafer 200 without making a gas phase reaction to form an adsorption layer of the material (TiCl₄) (hereinbelow, Ti containing layer). A chemical adsorption layer of TiCl₄ includes not only an adsorption layer in which TiCl₄ molecules are continuous but also a chemical adsorption layer in which TiCl₄ molecules are discontinuous.

At the same time, by opening the valve 523 to pass N₂ (inert gas) from the carrier gas supply pipe 520 connected to some midpoint in the gas supply pipe 320, flow of TiCl₄ into the nozzle 420 and the gas supply pipe 320 on the NH₃ side can be prevented. Since the purpose is to prevent flow-in of TiCl₄, the flow of N₂ (inert gas) controlled by the mass flow controller 522 may be low.

Removal of Residual Gas in Step S212

In step S212, residual gas such as residual TiCl₄ is removed from the processing chamber 201. The valve 313 of the gas supply pipe 310 is closed to stop the supply of TiCl₄ to the processing chamber 201 and the valve 612 is opened to pass TiCl₄to the vent line 610. By fully opening the APC valve 243 of the exhaust pipe 231, the processing chamber 201 is exhausted to 20 Pa or less by the vacuum pump 246 and the residual gas such as TiCl₄ remaining in the processing chamber 201 is eliminated from the processing chamber 201. At this time, by supplying the inert gas such as N₂ from the gas supply pipe 310 as a TiCl₄ supply line and, further, from the gas supply pipe 320 to the processing chamber 201, the effect of eliminating the residual gas such as residual TiCl₄ is increased.

Supply of NH₃ in Step S213

In step S213, NH₃ is supplied from the gas supply pipe 320 of the gas supply system 302 into the processing chamber 201 via the gas supply hole 421 of the nozzle 420.

The flow of NH₃ is adjusted by the mass flow controller 322 and the resultant gas is supplied from the gas supply pipe 320 into the processing chamber 201. Before NH₃ is supplied to the processing chamber 201, the valve 323 is closed and the valve 622 is opened to pass NH₃ to the vent line 620 via the valve 622. At the time of supplying NH₃ to the processing chamber 201, the valve 622 is closed and the valve 323 is opened to supply NH₃ to the gas supply pipe 320 on the downstream side of the valve 323, and the valve 523 is opened to supply carrier gas (N₂) from the carrier gas supply pipe 520. The flow of the carrier gas (N₂) is adjusted by the mass flow controller 522. NH₃ is joined together and mixed with the carrier gas (N₂) on the downstream side of the valve 323. The mixture is exhausted from the exhaust pipe 231 while being supplied to the processing chamber 201 via the gas supply hole 421 in the nozzle 420. At this time, the APC valve 243 is properly adjusted to maintain the pressure in the processing chamber 201 in the range from 30 to 1000 Pa, for example, at 70 Pa. The supply amount of NH₃ controlled by the mass flow controller 322 is set to the range of 5000 to 10,000 sccm, for example, 7,500 sccm. Time of exposing the wafer 200 to NH₃ lies in the range of 10 to 120 seconds and is, for example, 15 seconds. By controlling the power supply 250 for heating which supplies power to the heater 207, the temperature in the processing chamber 201 is held at, for example, 380° C. Since it takes time to change the temperature, preferably, the temperature is the same as that at the time of supplying the TiCl₄ gas.

At this time, the gas flowing in the processing chamber 201 is the NH₃ gas, and the TiCl₄ gas is not flowed to the processing chamber 201. Therefore, the NH₃ gas reacts with the titanium containing layer as the first layer formed on the wafer 200 in step S211 without making a gas phase reaction. As a result, the titanium containing layer is nitrided and modified to a second layer containing titanium (first element) and nitrogen (second element), that is, a titanium nitride layer (TiN layer).

At the same time, by opening the valve 513 to pass N₂ (inert gas) from the carrier gas supply pipe 510 connected to some midpoint in the gas supply pipe 310, flow of NH₃ into the nozzle 410 and the gas supply pipe 310 on the TiCl₄ side can be prevented. Since the purpose is to prevent flow-in of NH₃, the flow of N₂ (inert gas) controlled by the mass flow controller 512 may be low.

Removal of Residual Gas in Step S214

In step S214, residual gas such as residual NH₃ which was unreacted or contributed to the nitriding is removed from the processing chamber 201. The valve 323 of the gas supply pipe 320 is closed to stop the supply of NH₃ to the processing chamber 201 and the valve 622 is opened to pass NH₃ to the vent line 620. By fully opening the APC valve 243 of the exhaust pipe 231, the processing chamber 201 is exhausted to 20 Pa or less by the vacuum pump 246 and the residual gas such as NH₃ remaining in the processing chamber 201 is removed from the processing chamber 201. At this time, by supplying the inert gas such as N₂ from the gas supply pipe 320 as an NH₃ supply line and, further, from the gas supply pipe 310 to the processing chamber 201, the effect of eliminating the residual gas such as residual NH₃ is increased.

By setting the steps S211 to S214 as one cycle and performing the cycle at least once (step S215), a titanium nitride film having a predetermined thickness is formed on the wafer 200 by the ALD.

After performing the process of forming the titanium nitride layer having a predetermined thickness, by exhausting the processing chamber 201 while supplying the inert gas such as N₂ into the processing chamber 201, the processing chamber 201 is purged with the inert gas (gas purge in step S222). Preferably, the gas purge is performed by repeating supply of the inert gas such as N₂ into the processing chamber 201 by eliminating the residual gas, closing the APC valve 243, and opening the valves 513 and 523, stop of the supply of the inert gas such as N₂ to the processing chamber 201 by closing the valves 513 and 523, and vacuuming of the processing chamber 201 performed by opening the APC valve 243.

After that, the APC valve 243 is closed, the valves 513 and 523 are opened to replace the atmosphere in the processing chamber 201 with the inert gas such as N₂ (inert gas replacement), and the pressure in the processing chamber 201 is reset to the atmospheric pressure (resetting to atmospheric pressure in step S223). After that, the vacuum pump 246 is stopped.

In the processing chamber 201, the wafer 200 is cooled to a predetermined temperature, for example, 350° C.

The seal cap 219 is lowered by the boat elevator 115 to open the lower end of the attachment member 740, and the boat 217 is lowered in a state where the processed wafer 200 is mounted on the boat 217 and is carried out (unloaded) from the processing chamber 201 to the load lock chamber 710 (unloading of boat in step S224). After that, the gate valve 730 is closed.

At the time of lowering the boat 217, the boat 217 remains rotated by the boat rotating mechanism 267. After completion of the lowering of the boat 217 and cooling of the wafer 200 to the predetermined temperature (cooling of wafer in step S225), the boat rotating mechanism 267 is stopped to cease the rotation of the boat 217 (stop of rotation of boat in step S226). The boat 217 remains rotating since the rotation is started in step 203 until the rotation is stopped in step 226.

After that, the gate valve 770 is opened to open the wafer carry-in/out port 712. Referring to FIG. 1, the wafers 200 are sequentially carried out from the boat 217 in the load lock chamber 710 by the tweezers 125c of the wafer transfer mechanism 125a and transferred to the cassette 110 housed in the transfer rack 123 of the cassette rack 105 (discharging of wafers in step S227). In such a manner, one film forming process (batch process) is finished.

After that, the wafers 200 and the cassette 110 are properly carried to the outside of the casing 111 in a procedure opposite to the above.

In the embodiment, after formation of the TiN film, the wafer 200 is cooled to the desired temperature, for example, 350° C. in the processing chamber 201. After the cooling, the boat 217 filled with the wafers 200 is moved to the load lock chamber 710. The load lock chamber 710 is subjected to nitrogen-substitution and the atmosphere in the load lock chamber 710 is controlled to the concentration of oxidation components (oxygen, water, and the like) of 20 ppm or less. However, natural oxidation is caused in the TiN film even by the small amount of the oxidation components. In the case where natural oxidation occurs, titanium oxide having electric insulation is locally formed. At the time of seeing the TiN film as a conductive film in total, rise in electric resistance occurs. Since the oxidation component distribution and the temperature distribution in the load lock chamber 710 are biased, usually, the influence of the bias is exerted on the natural oxidation amount in the TiN film. The distribution in the plane of the wafer 200 of the natural oxidation amount is biased, the electric resistance distribution in the wafer plane becomes non-uniform, and there is the case such that the yield of a semiconductor device is influenced.

In the embodiment, to suppress the influence of the bias, while rotating the boat 217, that is, while rotating the wafers 200, the boat 217 filled with the wafers 200 is transferred from the processing chamber 201 to the load lock chamber 710. In such a manner, the in-plane distribution in the wafer 200 of the natural oxidation amount of the TiN film is uniformized, and the in-plane electricity resistance distribution of the wafer 200 can be uniformized. The rotational speed of the boat 217 at the time of transferring the boat 217 from the processing chamber 201 to the load lock chamber 710 is preferably 1 rpm to 10 rpm for the following reason. Since decrease in the actual temperature of the wafer in the load lock chamber is fast, the rotational speed of at least 1 rpm or higher is preferable.

### Second Embodiment

In the foregoing first embodiment, after formation of the TiN film, the wafers 200 are cooled to the desired temperature, for example, 350° C. in the processing chamber 201. After the cooling, the boat 217 filled with the wafers 200 is moved to the load lock chamber 710 while being rotated, thereby uniformizing the in-plane distribution of the wafer 200 of the natural oxidation amount of the TiN film and uniformizing the in-plane electric resistance distribution of the wafer 200. In the second embodiment, after formation of a TiN film, the TiN film is preliminarily oxidized in situ in the processing chamber 201, and the influence of natural oxidation at the time of transfer to the load lock chamber 710 is suppressed.

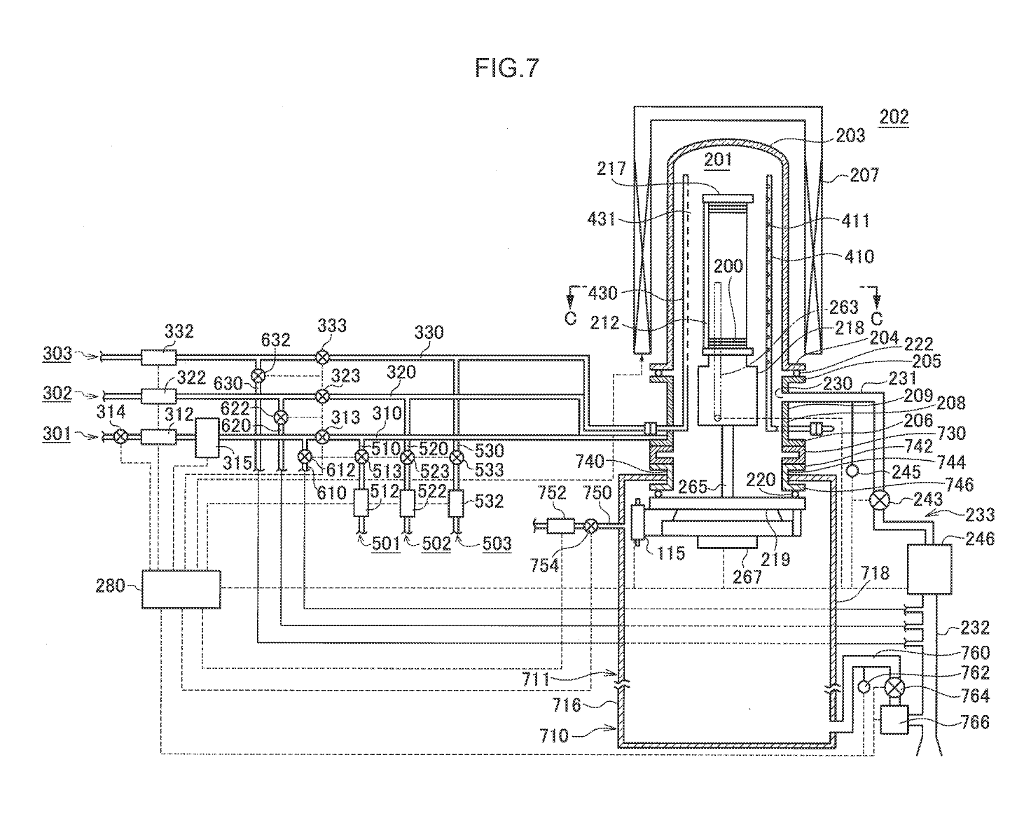

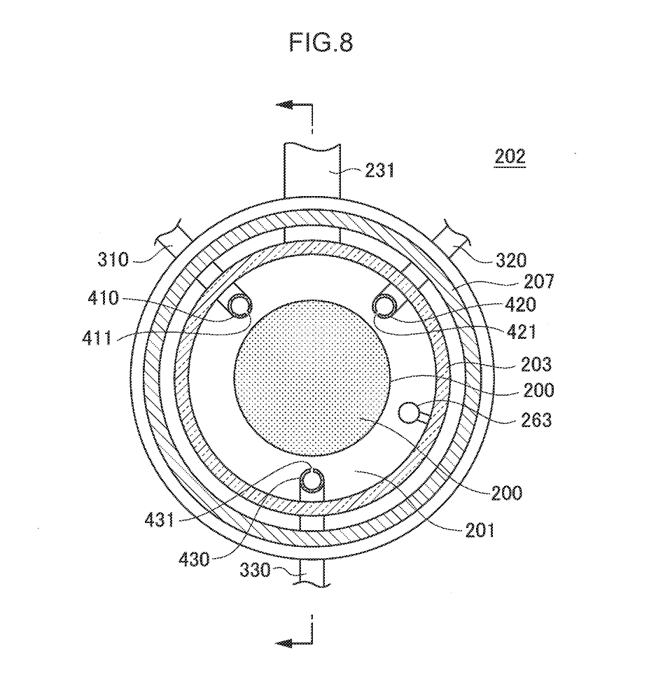

The substrate processing apparatus 101 of the second embodiment is similar to that of the first embodiment except that, as shown in FIGS. 7 and 8, a gas supply system 303, a carrier gas supply system (inert gas supply system) 503, and a nozzle 430 are added and, in association with the addition, mass flow controllers 332 and 532 and valves 333 and 533 which are controlled by the controller 280 are added.

With reference to FIGS. 7 and 8, the three gas supply systems (gas supply means) 301, 302, and 303 are provided, and the three carrier gas supply systems (inert gas supply systems) 501, 502, and 503 are provided. Since the gas supply systems (gas supply means) 301 and 302 and the carrier gas supply systems (inert gas supply systems) 501 and 502 are the same as those in the first embodiment, their description will not be repeated.

The gas supply system 303 added in the second embodiment is used as an oxygen-containing gas supply system for supplying oxygen containing gas to the processing chamber 201.

The gas supply system 303 includes a gas supply pipe 330. The gas supply pipe 330 is provided with, in order from the upstream side, a mass flow controller 332 as a flow controller (flow controlling unit) and a valve 333 as an open/close valve.

The downstream-side end of the gas supply pipe 330 penetrates the manifold 209, and the lower end of a nozzle 430 is connected to the front end of the gas supply pipe 330 in the manifold 209. The nozzle 430 extends in the vertical direction along the inner wall of the reaction tube 203 (the stack direction of the wafers 200) in a circular space between the inner wall of the reaction tube 203 and the wafers 200. A number of gas supply holes 431 for supplying material gas are provided in the side face of the nozzle 430. The gas supply holes 431 have the same opening area or opening areas which change from the bottom to the top and are provided at the same pitch. The gas supply holes 431 are open toward the center of the reaction tube 203.

Further, the gas supply pipe 330 is provided with, between the mass flow controller 332 and the valve 333, a vent line 630 connected to the exhaust pipe 232 which will be described later and a valve 632.

A gas supply system (gas supplying unit) 303 is constructed mainly by the gas supply pipe 330, the mass flow controller 332, the valve 333, the nozzle 430, the vent line 630, and the valve 632.

To the gas supply pipe 330, a carrier gas supply pipe 530 for supplying carrier gas is connected on the downstream side of the valve 333. The carrier gas supply pipe 530 is provided with a mass flow controller 532 and a valve 533. A carrier gas supply system (inert gas supply system, inactive gas supplying unit) 503 is constructed mainly by the carrier gas supply pipe 530, the mass flow controller 532, and the valve 533.

In the gas supply pipe 330, gaseous material gas is subjected to flow adjustment by the mass flow controller 332, and the resultant is supplied.

While no material gas is supplied to the processing chamber 201, the valve 333 is closed, the valve 632 is opened, and the material gas is passed to the vent line 630 via the valve 632.

At the time of supplying the material gas to the processing chamber 201, the valve 632 is closed, the valve 333 is opened, and the material gas is supplied to the gas supply pipe 330 on the downstream side of the valve 333. On the other hand, carrier gas is subjected to flow adjustment in the mass flow controller 532, and the resultant gas is supplied from the carrier gas supply pipe 530 via the valve 533. The material gas joins to the carrier gas on the downstream side of the valve 333, and the gases are supplied to the processing chamber 201 via the nozzle 430.

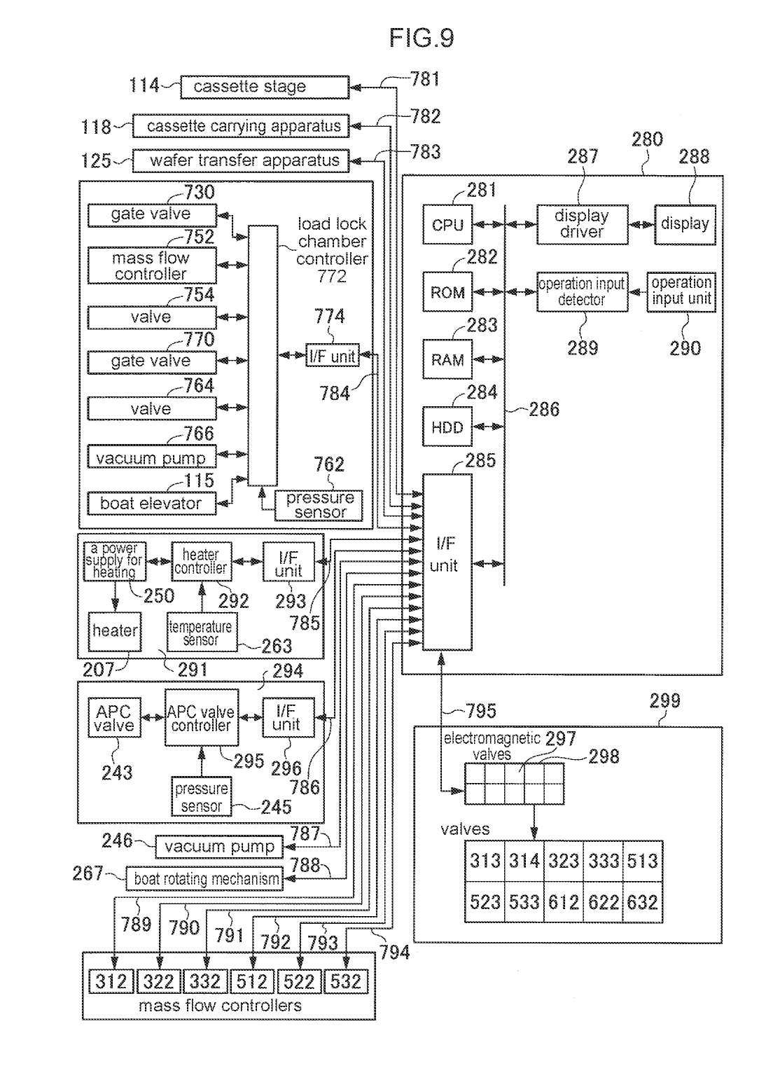

With reference to FIG. 9, as described above, the gas supply system 303 and the carrier gas supply system (inert gas supply system) 503 are added and, in association with the addition, the mass flow controllers 332 and 532 and the valves 333, 533, and 632 are added. Accordingly, cables 791 and 794 for connecting the mass flow controllers 332 and 532 and the communication I/F unit 285 of the controller 280 are added. To the electromagnetic valve group 298 of the valve controller 299, three electromagnetic valves 297 for controlling supply of air to the valves 333, 533, and 632 as added air valves are added. The other configuration is similar to that of the first embodiment. The controller 280 performs, in addition to the controls in the first embodiment, control of the flow of the added mass flow controllers 332 and 532 and control on the opening/closing operation of the valves 333, 533, and 632.

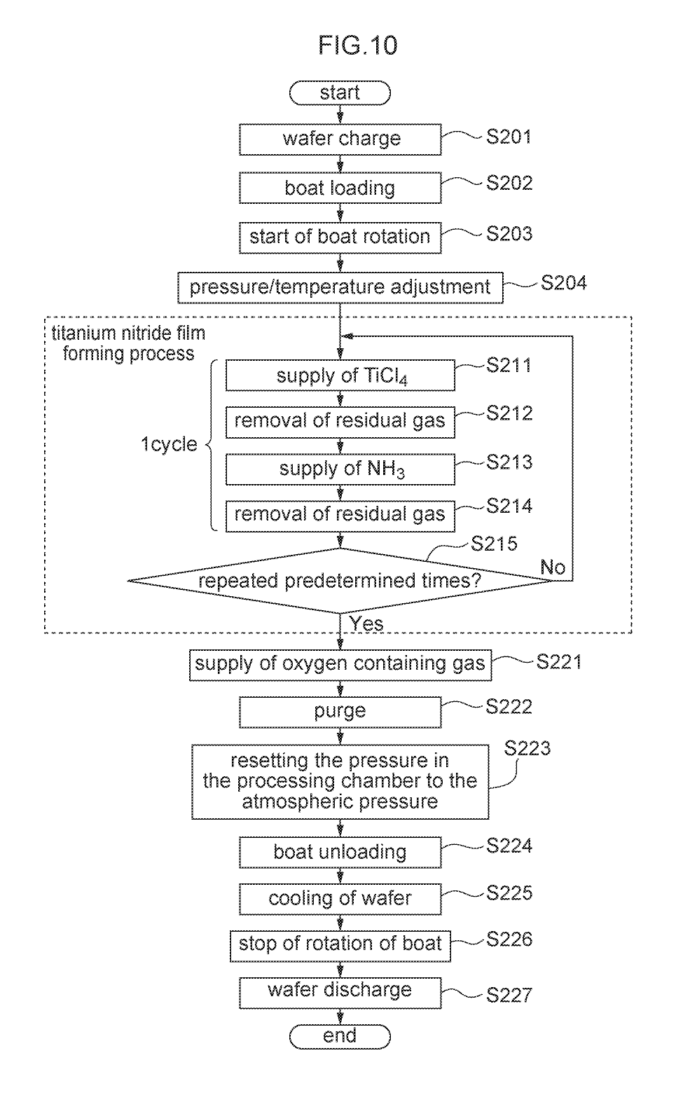

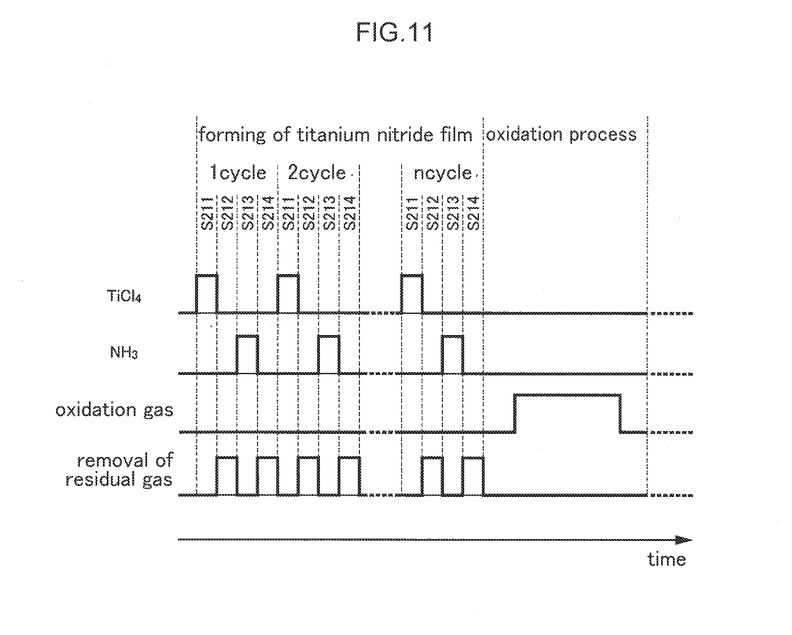

Next, a process of forming a titanium nitride (TiN) film on the silicon wafer 200 in the second embodiment by using the substrate processing apparatus 101 will be described with reference to FIGS. 1, 7, 10, and 11.

The second embodiment is the same as the first embodiment until the steps S211 to S214 as one cycle are performed at least once (step S215) to form a titanium nitride film having predetermined thickness on the wafer 200 by the ALD.

After the process of forming the titanium nitride film having a predetermined thickness is performed, for example, O₂ as oxygen containing gas is supplied from the gas supply pipe 330 of the gas supply system 303 into the processing chamber 201 via the gas supply hole 431 of the nozzle 430 (supply of oxygen containing gas in step S221).

The flow of O₂ is adjusted by the mass flow controller 332 and the resultant gas is supplied from the gas supply pipe 330 into the processing chamber 201. Before O₂ is supplied to the processing chamber 201, the valve 333 is closed and the valve 632 is opened to pass O₂ to the vent line 630 via the valve 632. At the time of supplying O₂ to the processing chamber 201, the valve 632 is closed and the valve 333 is opened to supply O₂ to the gas supply pipe 330 on the downstream side of the valve 333, and the valve 533 is opened to supply carrier gas (N₂) from the carrier gas supply pipe 530. The flow of the carrier gas (N₂) is adjusted by the mass flow controller 532. O₂ is joined together and mixed with the carrier gas (N₂) on the downstream side of the valve 333. The mixture is exhausted from the exhaust pipe 231 while being supplied to the processing chamber 201 via the gas supply hole 432 in the nozzle 430. At this time, the APC valve 243 is properly adjusted to maintain the pressure in the processing chamber 201 in the range from 50 to 100000 Pa, for example, at 100 Pa. The supply amount of O₂ controlled by the mass flow controller 332 is set to the range of 500 to 2,000 sccm, for example, 1,000 sccm. Time of exposing the wafer 200 to O₂ lies in the range of 10 to 60 seconds and is, for example, 20 seconds. By controlling the power supply 250 for heating which supplies power to the heater 207, the temperature in the processing chamber 201 is held at, for example, 320° C.

At the same time, by opening the valve 513 to pass N₂ (inert gas) from the carrier gas supply pipe 510 connected to some midpoint in the gas supply pipe 310 and by opening the valve 523 to pass N₂ (inert gas) from the carrier gas supply pipe 520 connected to some midpoint in the gas supply pipe 320, flow of O₂ into the nozzle 410 and the gas supply pipe 310 on the TiCl₄ side and the nozzle 420 and the gas supply pipe 320 on the NH₃ side can be prevented. Since the purpose is to prevent flow-in of O₂, the flow of N₂ (inert gas) controlled by the mass flow controllers 512 and 522 may be low.

Since the process following the gas purging in step S222 is the same as that of the first embodiment, its description will not be repeated.

In the embodiment, after formation of the titanium nitride film having predetermined thickness, for example, O₂ as oxygen containing gas is supplied into the processing chamber 201 (step S221), and the surface of the titanium nitride film is preliminarily oxidized in situ. By preliminarily oxidizing the surface of the titanium nitride film, the natural oxidation amount of the TiN film at the time of transfer of the board 217 filled with the wafers 200 from the processing chamber 201 to the load lock chamber 710 can be suppressed.

By supplying the oxygen containing gas such as O₂ into the processing chamber 201 and preliminarily oxidizing the surface of the titanium nitride film, the surface of the titanium nitride film can be oxidized in a controlled state. After that, natural oxidation in the TiN film which is beyond control and occurs at the time of the transfer from the processing chamber 201 to the load lock chamber 710 can be suppressed. As a result, the surface of the titanium nitride film can be oxidized more uniformly in the plane of the wafer 200, and the electric resistance distribution in the plane of the wafer 200 can be made more uniformly. By forming the TiN film as described above and, after that, performing after processing with dilute hydrofluoric acid (DHF) or the like, the titanium oxide on the surface is removed, and electric resistance can be recovered.

In the embodiment, by preliminarily oxidizing the surface of the titanium nitride film by supplying the oxygen containing gas such as O₂ into the processing chamber 201, the surface of the titanium nitride film can be oxidized in the controlled state. Consequently, in an apparatus of the batch process type for mounting a plurality of, for example, 100 to 150 pieces of wafers 200 on the boat 217 and processing them at a time, the oxidation amounts in the surfaces of the titanium nitride films among the wafers can be uniformized.

By preliminarily oxidizing the surface of the titanium nitride film, the natural oxidation amount of the TiN film at the time of transferring the boat 217 filled with the wafers 200 from the processing chamber 201 to the load lock chamber 710 can be suppressed. Therefore, even in the case of transferring the boat 217 filled with the wafers 200 from the processing chamber 201 to the load lock chamber 710 without rotating the boat 217, although the uniformity of the surface oxidation in the titanium nitride film is lower than that of the embodiment, the surface oxidation can be uniformized in the face of the wafer 200.

Although O₂ is used as the oxygen containing gas in the present embodiment, the gas is not limited to O₂. Any gas containing oxygen atoms such as O₃, H₂O, or H₂O₂ can be used.

Although the vaporizer 315 is used to vaporize the liquid material in the first and second embodiments, a bubbler may be used in place of the vaporizer.

In the case where the material supplied from the gas supply system 301 is gas, the liquid mass flow controller 312 is replaced with a gas mass flow controller, and the vaporizer 315 becomes unnecessary.

Although titanium tetrachloride (TiCl₄) is used as a Ti containing material in the first and second embodiments, in place of titanium tetrachloride (TiCl₄), tetrakis dimethylamino titanium (TDMAT, Ti[N(CH₃)₂]₄), tetrakis diethylamino titanium (TDEAT, Ti[N(CH₂CH₃)₂]₄), or the like may be used.

Although ammonia (NH₃) is used as a nitrogen containing gas, in place of ammonia (NH₃), nitrogen (N₂), nitrous oxide (N₂O), mono methyl hydrazine (CH₆N₂), or the like can be used.

By applying the material gas such as the Ti containing material gas or nitrogen containing gas with plasma, light, or microwave, the reaction may be accelerated.

In the foregoing first and second embodiments, in the case of forming the titanium nitride (TiN) film on the wafer 200 by using titanium tetrachloride (TiCl₄) and ammonia (NH₃), the uniformity of the natural oxide film after formation of the titanium nitride (TiN) film is improved. The invention can be also applied to improve the uniformity of natural oxidation in the surface after formation of another nitride film or another thin film.

Although the example of forming the titanium nitride film by the ALD in which a plurality of gases are alternately supplied without being mixed has been described, the invention is not limited to the example. Another gas supply method can be also applied. For example, in the case of using a plurality of kinds of gases, the gases may be supplied in pulses simultaneously (for example, a first process of simultaneously supplying the titanium containing gas and the nitrogen containing gas for predetermined time and a second process of eliminating the atmosphere in the processing chamber are alternately performed). The term “simultaneously” means that the gases may be mixed in a time zone. The supply start timing and the supply stop timing may not be always the same.

While continuously supplying at least one kind of gas, another gas may be supplied in pulses (for example, while continuously supplying the nitrogen containing gas, supply of the titanium containing gas, stop, and exhaust of the processing chamber are repeated).

For example, in the case of using a plurality of kinds of gases, the plurality of kinds of gases may not be supplied simultaneously but may be simultaneously supplied from the beginning to the end of the film formation (CVD).

Although N₂ (nitrogen) is used as the carrier gas in the foregoing embodiments, in place of nitrogen, He (helium), Ne (neon), Ar (argon), or the like may be used.

In the foregoing first and second embodiments, either an inorganic metal compound or an organic metal compound containing Ti as a component (hereinbelow, Ti source) is supplied from the gas supply system 301, either an inorganic metal compound or an organic metal compound containing N as a component (hereinbelow, N source) is supplied from the gas supply system 301, and the supplied compounds are allowed to react with each other, thereby forming titanium nitride on the wafer 200 in which a conductor film, an insulating film, or a conductor pattern separated by an insulating film is exposed. In such a case, the amount and uniformity of natural oxidation which occurs when the wafer 200 is carried out from the processing chamber 201 may be controlled by using an apparatus having an atmosphere controller such as the load lock chamber or the N₂ purge chamber adjacent to the processing chamber 201.

After formation of the titanium nitride film, by carrying out the wafer 200 while being rotated from the processing chamber 201 and transferring it to a cooling stage, the natural oxidation amount of the titanium nitride film is uniformized in the wafer plane.

By positively oxidizing the only very surface in advance in situ after formation of the titanium nitride film, the amount of natural oxidation which occurs when the wafer 200 is carried out from the processing chamber 201 can be controlled.

By using a batch furnace capable of processing the plurality of wafers 200 simultaneously, as compared with the case of processing one or a few wafers 200 simultaneously, equivalent film quality can be achieved with higher productivity or a thin film of higher quality while assuring equivalent productivity can be provided.

It is also preferable that the processing furnace 202 is a portrait-type furnace in which a plurality of wafers 200 are arranged in the vertical direction and processed and has a structure that an inner tube having almost the same diameter as that of the wafer 200 exists in the reaction tube 203, and gas is introduced/exhausted from the side, to/from the gap between the wafers 200 and the inside of the inner tube.

It is also preferable that the processing furnace 202 is a single-wafer-processing furnace in which the wafers 200 are processed one by one.

### Preferred Modes of the Preferred Embodiments

Preferred modes of the preferred embodiments will be additionally described below.

(Additional Description 1)

According to an aspect of the preferred embodiments, there is provided a substrate processing apparatus including:

a substrate supporting member that supports a substrate;

a processing chamber capable of housing the substrate supporting member;

a rotating mechanism that rotates the substrate supporting member;

a carrying mechanism that carries out the substrate supporting member from the processing chamber;

a material gas supply system that supplies material gas into the processing chamber;

a nitrogen-containing-gas supply system that supplies nitrogen containing gas into the processing chamber; and

a controller that controls the material gas supply system, the nitrogen-containing-gas supply system, the carrying mechanism, and the rotating mechanism, after forming a nitride film on the substrate by using the material gas and the nitrogen containing gas, to carry out the substrate supporting member that supports the substrate while being rotated from the processing chamber.

(Additional Description 2)

In the substrate processing apparatus according to the additional description 1, preferably, the controller controls the carrying mechanism and the rotating mechanism to control rotational speed of the substrate supporting member at the time of carrying out the substrate supporting member that supports the substrate from the processing chamber while rotating the substrate supporting member so that amount of natural oxidation in the nitride film formed on the substrate becomes uniform in a plane of the substrate.

(Additional Description 3)

In the substrate processing apparatus according to the additional description 1 or 2, preferably, the substrate processing apparatus further includes:

an oxygen-containing-gas supply system that supplies oxygen containing gas into the processing chamber,

wherein, after formation of the nitride film on the substrate and before carriage of the substrate supporting member from the processing chamber, the controller controls the material gas supply system, the nitrogen-containing-gas supply system, the carrying mechanism, the rotating mechanism, and the oxygen-containing-gas supply system so as to supply the oxygen containing gas to the processing chamber to oxidize a surface of the nitride film.

(Additional Description 4)

In the substrate processing apparatus according to any one of the additional descriptions 1 to 3, preferably, the substrate processing apparatus further includes a load lock chamber which is adjacent to the processing chamber and into which the substrate supporting member carried out from the processing chamber is carried by the carrying mechanism.

(Additional Description 5)

In the substrate processing apparatus according to the additional description 4, preferably, the substrate processing apparatus further includes an inert gas supply system that supplies inert gas to the load lock chamber and an exhausting unit that exhausts the load lock chamber,

wherein, before the substrate supporting member is carried out from the processing chamber into the load lock chamber, the controller controls the material gas supply system, the nitrogen-containing-gas supply system, the carrying mechanism, the rotating mechanism, the inert gas supply system, and the exhausting unit so as to set the inside of the load lock chamber to the inert gas atmosphere.

(Additional Description 6)

In the substrate processing apparatus according to the additional description 5, preferably, the substrate processing apparatus further includes a blocking member which moves interlockingly with the carrying mechanism, when the substrate supporting member is housed in the processing chamber, for hermetically closing the processing chamber and the load lock chamber and, when the substrate supporting member is carried out from the processing chamber, making the processing chamber and the load lock chamber communicated with each other,

wherein, before a nitride film is formed on the substrate, the controller hermetically closes the processing chamber and the load lock chamber by the blocking member, before the substrate supporting member is carried out from the processing chamber into the load lock chamber and, in a state where the processing chamber and the load lock chamber are hermetically closed by the blocking member, the controller controls the material gas supply system, the nitrogen-containing-gas supply system, the carrying mechanism, the rotating mechanism, the inert gas supply system, and the exhausting unit so as to set the inside of the load lock chamber to the inert gas atmosphere.

(Additional Description 7)

In the substrate processing apparatus according to any one of the additional descriptions 1 to 6, preferably, the substrate processing apparatus further includes a temperature controller that controls temperature in the processing chamber,

wherein, after the substrate is heated to first predetermined temperature and a nitride film is formed on the substrate by using the material gas and the nitrogen containing gas and, after the temperature of the substrate is set to second predetermined temperature lower than the first predetermined temperature in the processing chamber, the controller controls the material gas supply system, the nitrogen-containing-gas supply system, the carrying mechanism, the rotating mechanism, and the temperature controller so as to carry the substrate supporting member that supports the substrate from the processing chamber while rotating the substrate supporting member.

(Additional Description 8)

According to another aspect of the preferred embodiments, there is provided a substrate processing apparatus including:

a substrate supporting member that supports a substrate;

a processing chamber capable of housing the substrate supporting member;

a carrying mechanism that carries out the substrate supporting member from the processing chamber;

a material gas supply system that supplies material gas into the processing chamber;

a nitrogen-containing-gas supply system that supplies nitrogen containing gas into the processing chamber;

an oxygen-containing-gas supply system that supplies oxygen containing gas into the processing chamber; and

a controller that controls the material gas supply system, the nitrogen-containing-gas supply system, the oxygen-containing-gas supply system, and the carrying mechanism, after forming a nitride film on the substrate by using the material gas and the nitrogen containing gas, to supply the oxygen containing gas to the processing chamber to oxidize a surface of the nitride film, and thereafter to carry out the substrate supporting member that supports the substrate from the processing chamber.

(Additional Description 9)

In the substrate processing apparatus according to any one of the additional descriptions 1 to 8, preferably, the material gas is Ti containing material gas.

(Additional Description 10)

In the substrate processing apparatus according to the additional description 9, preferably, the material gas is gas obtained by vaporizing a liquid Ti containing material.

(Additional Description 11)

In the substrate processing apparatus according to the additional description 10, preferably, the material gas is gas obtained by vaporizing TiCl₄.

(Additional Description 12)

In the substrate processing apparatus according to any one of the additional descriptions 1 to 11, preferably, the nitrogen containing gas is NH₃.

(Additional Description 13)

According to a still another aspect of the preferred embodiments, there is provided a method of manufacturing a semiconductor device, including:

carrying a plurality of substrates into a processing chamber;

forming a film on each of the plurality of substrates by supplying a plurality of gases to the processing chamber; and

carrying out the plurality of substrates from the processing chamber so that an amount of natural oxidation on a surface of the film formed on each of the plurality of substrates becomes a predetermined value in a plane of the substrate.

(Additional Description 14)

According to a still another aspect of the preferred embodiments, there is provided a method of manufacturing a semiconductor device, including:

carrying a substrate supporting member that supports a substrate into a processing chamber;

supplying a material gas and a nitrogen containing gas to the processing chamber to form a nitride film on the substrate; and

carrying out the substrate supporting member that supports the substrate on which the nitride film is formed from the processing chamber while rotating the substrate supporting member.

(Additional Description 15)

In the substrate processing apparatus according to the additional description 14, preferably, the method further includes: supplying an oxygen containing gas to the processing chamber to oxidize of the nitride film after forming the nitride film on the substrate and before carrying out the substrate supporting member from the processing chamber.

(Additional Description 16)

According to a still another aspect of the preferred embodiments, there is provided a method of manufacturing a semiconductor device, including:

carrying a substrate supporting member that supports a substrate into a processing chamber;

supplying a material gas and a nitrogen containing gas to the processing chamber to form a nitride film on the substrate;

supplying an oxygen containing gas to the processing chamber to oxidize a surface of the nitride film; and

carrying out the substrate supporting member that supports the substrate on which the nitride film whose surface is oxidized is formed from the processing chamber.

(Additional Description 17)

According to a still another aspect of the preferred embodiments, there is provided a method of manufacturing a semiconductor device, including:

carrying a substrate into a processing chamber;

supplying a material gas and a nitrogen containing gas to the processing chamber to form a nitride film on the substrate;

supplying an oxygen containing gas to the processing chamber to oxidize a surface of the nitride film; and

thereafter carrying out the substrate from the processing chamber. and

thereafter removing an oxidized film on the surface of the nitride film.

(Additional Description 18)

According to a still another aspect of the preferred embodiments, there is provided a method of manufacturing a semiconductor device, including:

forming a nitride film on a substrate by supplying a material gas and a nitrogen containing gas into a processing chamber accommodating a substrate supporting member that supports the substrate, by controlling a material gas supply system that supplies the material gas to the processing chamber and a nitrogen-containing-gas supply system that supplies the nitrogen containing gas to the processing chamber; and

controlling a rotating mechanism that rotates the substrate supporting member and a carrying-out mechanism that carries out the substrate supporting member from the processing chamber to carry out the substrate supporting member supporting the substrate on which the nitride film is formed from the processing chamber while rotating the substrate supporting member.

(Additional Description 19)

According to a still another aspect of the preferred embodiments, there is provided a semiconductor device manufactured by the methods of manufacturing a semiconductor device according to any one of the additional descriptions 13 to 18.

(Additional Description 20)

According to a still another aspect of the preferred embodiments, there is provided a program that causes computer to perform a process including:

controlling a material gas supply system that supplies a material gas to a processing chamber and a nitrogen-containing-gas supply system that supplies a nitrogen containing gas to the processing chamber to supply the material gas and the nitrogen containing gas into the processing chamber accommodating a substrate supporting member that supports a substrate and to form a nitride film on the substrate; and

controlling a rotating mechanism that rotates the substrate supporting member and a carrying-out mechanism that carries out the substrate supporting member from the processing chamber to carry out the substrate supporting member supporting the substrate on which the nitride film is formed from the processing chamber while rotating the substrate supporting member after forming the nitride film.

(Additional Description 21)

According to a still another aspect of the preferred embodiments, there is provided a non-transitory computer-readable medium storing the program according to the additional description 20.

(Additional Description 22)

According to a still another aspect of the preferred embodiments, there is provided a substrate processing apparatus including the non-transitory computer-readable medium according to the additional description 21.

(Additional Description 23)

According to a still another aspect of the preferred embodiments, there is provided a film forming apparatus for forming titanium nitride on a substrate to be processed on which a conduction film, an insulation film, or a conductor pattern separated by an insulation film is exposed, by causing a reaction between either an inorganic metal compound or an organic metal compound containing Ti as a component (hereinbelow, called Ti source) and either an inorganic metal compound or an organic metal compound containing N as a component (hereinbelow, called N source),

wherein an atmosphere control chamber such as a load lock chamber or an N₂ purge chamber adjacent to a processing chamber is provided, to control amount of natural oxidation which occurs when a substrate to be processed is carried from the processing chamber to the atmosphere control chamber and its uniformity.

(Additional Description 24)

In the film forming apparatus according to the additional description 23, preferably, at the time of carrying out the substrate to be processed from the processing chamber to a cooling stage after film formation, by carrying the substrate to be processed while being rotated, the amount of natural oxidation in a titanium nitride film is uniformed in a plane of the substrate to be processed.

(Additional Description 25)

In the film forming apparatus according to the additional description 23, preferably, after formation of the titanium nitride film, by preliminarily positively oxidizing only a very surface in situ, the amount of natural oxidation which occurs when the substrate to be processed is carried out from the processing chamber is controlled.

(Additional Description 26)

In the film forming apparatus according to any one of the additional descriptions 23 to 25, preferably, the Ti source is TiCl₄.

(Additional Description 27)

In the film forming apparatus according to any one of the additional descriptions 23 to 26, preferably, the N source is NH₃.

(Additional Description 28)

In the film forming apparatus according to any one of the additional descriptions 23 to 27, preferably, the film forming apparatus is a batch furnace capable of simultaneously processing a plurality of substrates to be processed.

(Additional Description 29)

In the film forming apparatus according to the additional description 28, preferably, the film forming apparatus is a portrait-type furnace in which a plurality of substrates to be processed are arranged in the vertical direction and processed and has a structure that an inner tube having a diameter which is almost the same as that of a substrate to be processed exists in a reaction tube of the furnace, and gas is introduced and exhausted from a side, to/from a gap between the substrates to be processed and the inside of the inner tube.

(Additional Description 30)

In the film forming apparatus according to any one of the additional descriptions 23 to 27, preferably, the film forming apparatus is a single-wafer-processing furnace in which substrates to be processed are processed one by one.

(Additional Description 31)

According to a still another aspect of the preferred embodiments, there is provided a film forming method for forming titanium nitride on a substrate to be processed, on which a conduction film, an insulation film, or a conductor pattern separated by an insulation film is exposed, by causing a reaction between either an inorganic metal compound or an organic metal compound containing Ti as a component (hereinbelow, called Ti source) and either an inorganic metal compound or an organic metal compound containing N as a component (hereinbelow, called N source), wherein a film forming apparatus having an atmosphere control chamber such as a load lock chamber or an N₂ purge chamber adjacent to a processing chamber is used to control amount of natural oxidation which occurs when a substrate to be processed is carried from the processing chamber to the atmosphere control chamber and its uniformity.

Various exemplary embodiments of the invention have hitherto been described, however, the invention is not limited to the exemplary embodiments. Therefore, the scope of the invention is limited only by the appended claims.

What is claimed is:

1. A substrate processing apparatus comprising:
a substrate supporting member that supports a substrate;
a processing chamber capable of housing the substrate supporting member;
a rotating mechanism that rotates the substrate supporting member;
a carrying mechanism that carries out the substrate supporting member from the processing chamber;
a material gas supply system that supplies material gas into the processing chamber;
a nitrogen-containing-gas supply system that supplies nitrogen containing gas into the processing chamber; and
a controller that controls the material gas supply system, the nitrogen-containing-gas supply system, the carrying mechanism, and the rotating mechanism, after forming a nitride film on the substrate by using the material gas and the nitrogen containing gas, to carry out the substrate supporting member that supports the substrate while being rotated from the processing chamber.

2. A substrate processing apparatus according to claim 1, wherein the controller controls the carrying mechanism and the rotating mechanism to control rotational speed of the substrate supporting member at the time of carrying out the substrate supporting member that supports the substrate from the processing chamber while rotating the substrate supporting member so that amount of natural oxidation in the nitride film formed on the substrate becomes uniform in a plane of the substrate.

3. A substrate processing apparatus according to claim 1, further comprising:
an oxygen-containing-gas supply system that supplies oxygen containing gas into the processing chamber,
wherein, after formation of the nitride film on the substrate and before carriage of the substrate supporting member from the processing chamber, the controller controls the material gas supply system, the nitrogen-containing-gas supply system, the carrying mechanism, the rotating mechanism, and the oxygen-containing-gas supply system so as to supply the oxygen containing gas to the processing chamber to oxidize a surface of the nitride film.

4. A method of manufacturing a semiconductor device, including:
carrying a plurality of substrates into a processing chamber;
forming a film on each of the plurality of substrates by supplying a plurality of gases to the processing chamber; and
carrying out the plurality of substrates from the processing chamber so that an amount of natural oxidation on a surface of the film formed on each of the plurality of substrates becomes a predetermined value in a plane of the substrate.

5. A method of manufacturing a semiconductor device, including:
carrying a substrate supporting member that supports a substrate into a processing chamber;
supplying a material gas and a nitrogen containing gas to the processing chamber to form a nitride film on the substrate; and
carrying out the substrate supporting member that supports the substrate on which the nitride film is formed from the processing chamber while rotating the substrate supporting member.

6. A method of manufacturing a semiconductor device, including:
carrying a substrate into a processing chamber;
supplying a material gas and a nitrogen containing gas to the processing chamber to form a nitride film on the substrate;
supplying an oxygen containing gas to the processing chamber to oxidize a surface of the nitride film; and
thereafter carrying out the substrate from the processing chamber. and
thereafter removing an oxidized film on the surface of the nitride film.
